(19) United States
(12) Patent Application Publication
(10) Pub. No.: US 2025/0271509 A1
(43) Pub. Date: Aug. 28, 2025

(54) METHOD AND DEVICE FOR BROKEN CONDUCTOR DETECTION, PROGRAM PRODUCT AND RELAY PROTECTION DEVICE

(71) Applicant: Schneider Electric Industries SAS, Rueil-Malmaison (FR)

(72) Inventor: Jinlei Xing, Shanghai (CN)

(73) Assignee: Schneider Electric Industries SAS, Rueil-Malmaison (FR)

(21) Appl. No.: 18/882,169

(22) Filed: Sep. 11, 2024

(30) Foreign Application Priority Data
Feb. 28, 2024 (CN) 202410225495.1

(51) Int. Cl. G01R 31/58; G01R 31/08; H02J 13/00

(52) U.S. Cl. CPC G01R 31/58; G01R 31/085; H02J 13/0004

(57) ABSTRACT

A method of broken conductor detection for a power system is disclosed. The method includes: determining whether a first condition is satisfied; based on determining that the first condition is satisfied, receiving information of a second voltage phasor associated with a second detection point and synchronized with information of a first voltage phasor; determining a linked impedance between the first detection point and the second detection point based on the information of the first current phasor, the information of the first voltage phasor and the information of the second voltage phasor; and determining that a broken conductor exists between the first detection point and the second detection point based on the linked impedance being greater than a second threshold. Furthermore, a detection device for broken conductor detection of an electric power system, a computer program product and a relay protection device are disclosed.

### TECHNICAL FIELD

The present disclosure relates to the field of broken conductor detection, in particular to a method and a detection device for broken conductor detection of an electric power system, a computer program product and a relay protection device.

### BACKGROUND

Power systems play an important role in people's daily lives. There are a variety of failure possibilities in a power system with a complex structure, wherein a broken conductor fault can not only cause a power outage of key electrical loads, but can lead to serious consequences such as fires due to a broken conductor being grounded or lapped on a tree. Broken conductor detection of power systems is critical in both economic and safety aspects.

### SUMMARY

Embodiments of the present disclosure provide a method, a detection device, a computer program product, and a relay protection device for broken conductor detection of an electric power system. The method, the detection device, the computer program product and the relay protection device determine whether there is a broken conductor by calculating the linked impedance between the detection points based on the current phasor and the voltage phasor of the detection points, which is simple to set up and easy to implement.

Embodiments of the present disclosure provide a method for broken conductor detection of a power system, including: determining whether a first condition is satisfied based on information of a first current phasor associated with a first detection point in the power system, wherein the first condition is that a magnitude of a change of the first current phasor over a predetermined time period between a first time point and a second time point is greater than a predetermined first threshold; based on determining that the first condition is satisfied, receiving information of a second voltage phasor associated with a second detection point and synchronized with information of a first voltage phasor associated with the first detection point, wherein the second detection point is a detection point in the power system that is adjacent to the first detection point; determining a linked impedance between the first detection point and the second detection point based on the information of the first current phasor, the information of the first voltage phasor and the information of the second voltage phasor; and determining that a broken conductor exists between the first detection point and the second detection point based on the linked impedance being greater than a predetermined second threshold.

According to an embodiment of the present disclosure, the information of the first current phasor comprises a phasor of the first current phasor at the first time point and a phasor of the first current phasor at the second time point, the information of the first voltage phasor comprises a phasor of the first voltage phasor at the first time point and a phasor of the first voltage phasor at the second time point.

According to an embodiment of the present disclosure, the information of the second voltage phasor comprises a magnitude of a phasor of the second voltage phasor at the second time point and a magnitude of a changing phasor of the second voltage phasor over the predetermined period of time, and wherein determining the linked impedance comprises calculating an approximation of the linked impedance.

According to an embodiment of the present disclosure, the approximation of the linked impedance is calculated based on the following equation:

$${Z}_{12} \approx \frac{\vert Δ {\dot{U}}_{1} \vert \vert {\dot{U}}_{2} \vert - \vert Δ {\dot{U}}_{2} \vert \vert {\dot{U}}_{1} \vert}{\vert Δ {\dot{I}}_{1} {\dot{U}}_{1} - Δ {\dot{U}}_{1} {\dot{I}}_{1} \vert}$$

wherein Z₁₂ represents the linked impedance, \dot{U}₁ represents the phasor of the first voltage phasor at the second time, Δ\dot{U}₁ represents the difference between the phasor of the first voltage phasor at the second time and the phasor at the first time, \dot{U}₂ represents the phasor of the second voltage phasor at the second time, Δ\dot{U}₂ represents the difference between the phasor of the second voltage phasor at the second time and the phasor at the first time, İ₁ represents the phasor of the first current phasor at the second time, Δİ₁ represents the difference between the phasor of the first current phasor at the second time and the phasor at the first time, and |·| represents the magnitude of the phasor.

According to an embodiment of the present disclosure, the information of the second voltage phasor comprises a phasor of the second voltage phasor at the first time point and a phasor of the second voltage phasor at the second time point, and wherein determining the linked impedance comprises calculating an actual value of the linked impedance.

According to an embodiment of the present disclosure, the actual value of the linked impedance is calculated based on the following equation:

$${Z}_{12} = \vert \frac{Δ {\dot{U}}_{1} {\dot{U}}_{2} - Δ {\dot{U}}_{2} {\dot{U}}_{1}}{Δ {\dot{I}}_{1} {\dot{U}}_{1} - Δ {\dot{U}}_{1} {\dot{I}}_{1}} \vert$$

wherein Z₁₂ represents the linked impedance, \dot{U}₁ represents the phasor of the first voltage phasor at the second time, Δ\dot{U}₁ represents the difference between the phasor of the first voltage phasor at the second time and the phasor of the first voltage phasor at the first time, \dot{U}₂ represents the phasor of the second voltage phasor at the second time, Δ\dot{U}₂ represents the difference between the phasor of the second voltage phasor at the second time and the phasor of the second voltage phasor at the first time, İ₁ represents the phasor of the first current phasor at the second time, Δİ₁ represents the difference between the phasor of the first current phasor at the second time and the phasor of the first current phasor at the first time, and |·| represents the magnitude of the phasor.

According to an embodiment of the present disclosure, determining the second threshold based on the line impedance between the first detection point and the second detection point.

Embodiments of the present disclosure relate to a detection device for broken conductor detection of a power system, including: at least one processor; and at least one memory in which is stored an executable program which, when the executable program executed by the at least one processor, performs the method according to one of the embodiments of the present disclosure.

Embodiments of the present disclosure relate to a computer program product including computer commands for implementing the method according to one of the embodiments of the present disclosure when executed by a processor.

Embodiments of the present disclosure relate to a relay protection device including the detection device according to an embodiment of the present disclosure and a disconnection device that disconnects the first detection point from the power system based on the detection device determining that there is a broken conductor between the first detection point and the second detection point.

### BRIEF DESCRIPTION OF DRAWINGS

In order to more clearly illustrate the technical solutions of the embodiments of the present disclosure, the accompanying drawings required to be used in the description of the embodiments will be briefly described below. Obviously, the accompanying drawings in the description below are only exemplary embodiments of the present disclosure, and other accompanying drawings can be obtained according to these accompanying drawings without creative work for persons having ordinary skill in the art.

FIG. 1A and FIG. 1B exemplarily illustrate a schematic diagram of a section of a power system and an electrical equivalent schematic diagram, respectively;

FIG. 2A and FIG. 2B exemplarily illustrate schematic diagrams of normal operation and broken conductor faults, respectively, in a three-phase connection diagram;

FIG. 3 illustrates a schematic diagram of detection points according to an embodiment of the present disclosure;

FIG. 4 illustrates a schematic flow diagram of a method for broken conductor detection of a power system according to an embodiment of the present disclosure;

FIG. 5A and FIG. 5B illustrate schematic diagrams of simulation results of a method according to an embodiment of the present disclosure;

FIG. 6 illustrates a schematic diagram of a detection device according to an embodiment of the present disclosure;

FIG. 7 illustrates a schematic diagram of a computer program product according to an embodiment of the present disclosure;

FIG. 8 illustrates a schematic diagram of a relay protection device according to an embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. It is understood that the present disclosure is not limited by the example embodiments described herein.

In the present specification and the accompanying drawings, substantially same or similar steps and elements are represented by the same or similar reference numerals, and repeated descriptions of these steps and elements will be omitted. Meanwhile, the terms “first,” “second,” etc., which are used in the description and the claims of the present application for disclosure, are not intended to indicate any sequence, amount or importance, but for distinguishing various components.

Unless otherwise defined, all technical and scientific terms used herein have the same meanings as commonly understood by those skilled in the art of the present disclosure. The terms used herein are only for the purpose of describing the embodiments of the disclosure and are not intended to limit the disclosure.

With respect to the broken conductor detection, in a mainstream solution, the broken conductor detection is performed using the ratio of the negative sequence current and the positive sequence current, which cannot detect the broken conductor fault on the full line, has more detection blind sections, and the faulty lines cannot be cut in a small range after the broken conductor is detected, and the influence on the power system is large. In another mainstream solution, broken conductor detection is performed by means of a PMU (Grid Synchronous Phasor Measurement Unit), which has high requirements on synchronization accuracy, requires high cost-based communication infrastructure, and can only be performed when the current change after a broken conductor complies with more demanding requirements, e.g. more than 20% of the rated current.

In order to solve the above-mentioned problems of the prior art, such as blind sections for broken conductor detection or greater influence of broken conductor protection on a power system or higher data synchronization accuracy requirement, the present disclosure provides a method, a detection device, a computer program product and a relay protection device for broken conductor detection of a power system. The method, the detection device, the computer program product and the relay protection device calculate the linked impedance between the detection points based on the current phasor and the voltage phasor of the detection points, are simple to set up and easy to implement. Further, data communication is performed only after a certain degree of fluctuation of the current phasor is detected, reducing communication costs, and furthermore, based on the method, the detection device, the computer program product and the relay protection device, selective power outages of the lines between detection points can be achieved without affecting the normal operation of other parts of the power system.

To facilitate the description of the present disclosure, concepts related to the present disclosure are introduced below.

Grid: An intermediate link in a power system that establishes a channel for power delivery. Electrical elements such as electrical loads do not belong to the grid, and electrical lines are involved between two nodes (for example power plants, substations, electrical breakers, demarcation switches and the like) in the grid.

Line impedance: The impedance of the electrical line itself between two nodes in the power grid.

Linked impedance: The impedance of an electrical connection between two nodes in the power grid. The electrical connection between two nodes may involve an electrical load or the like.

Section of a power system: A constituent part of a power system between two nodes in a grid, which may include, for example, a portion associated with the grid between the two nodes and a portion associated with a consumer load or a distributed power source between the two nodes.

T-connected line: Another line from the line supplying power from A to B to supply power to C, or a branch connection in an electrical main connection line.

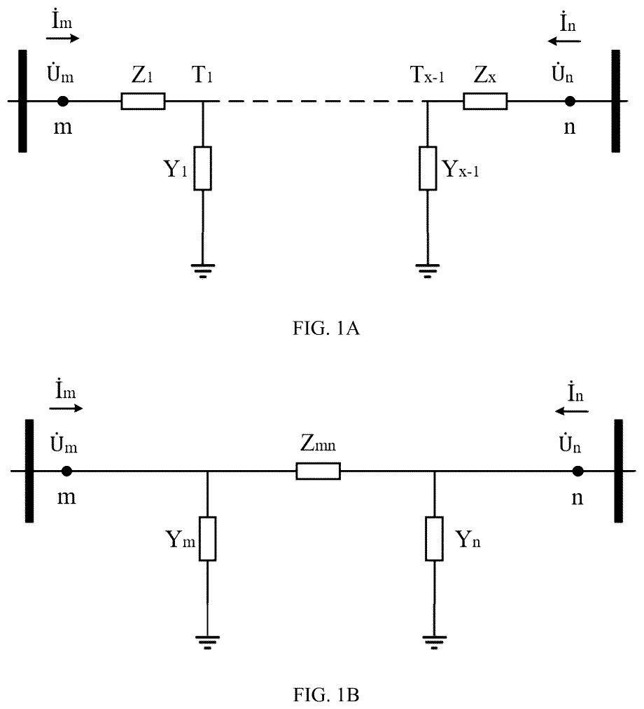

FIG. 1A and FIG. 1B exemplarily illustrate a schematic diagram of a section of a power system and an electrical equivalent schematic diagram, respectively.

FIG. 1A exemplarily illustrates a schematic diagram of a section of a power system.

As shown in FIG. 1A, an exemplary section between two nodes m, n of a power system may include a line mn, x-1 T-connected lines tapped from the line mn, and electrical loads respectively connected on the respective T-connected lines. The x-1 T-connected lines have T-connected points T₁ to Tₓ₋₁ with the line mn, respectively, the electrical loads respectively connected on the T-connected lines being represented by the admittances Y1 to Yₓ₋₁. The lines themselves have impedances, e.g., the line between node m and T-connected point T₁ has impedance Z₁, the line between T-connected point T₁ and T-connected point T₂ has impedance Z₂ (not shown), the line between T-connected point Tₓ₋₁ and node n has impedance Zx, etc.

FIG. 1B exemplarily illustrates an electrical equivalent schematic of the section of FIG. 1A. In FIG. 1B, x-1 T-connected lines tapped from a line mn between two nodes m, n are equivalently π-type lines, the electrical loads of this exemplary section of the power system are equivalently admittances Yₘ and Yₙ, and the line impedance between nodes m, n is equivalently equivalent impedance Zₘₙ.

In practice, the impedance of the line is much less than that of an equivalent load, e.g. the line has an impedance of about 2 ohms per 10 km. Thus, in a normally operating grid, the linked impedance between two nodes in a line is approximately equal to the impedance of the line between the two nodes, and with reference to FIG. 1A and FIG. 1B, this relationship is represented by:

$${Z}_{mn} \approx {\sum }_{i = 1}^{x} {Z}_{i} \qquad ( 1 )$$

That is, in a normally operating grid, the linked impedance between two nodes in a line is substantially determined by the impedance of the line itself between the two nodes and is almost unchanged.

By electrical equivalence, the actual value of the equivalent impedance Zₘₙ is calculated with the following equations:

$${\dot{U}}_{m} - {\dot{U}}_{n} = ( {\dot{I}}_{m} - {Y}_{m} {\dot{U}}_{m} ) {Z}_{mn} \qquad ( 2 )$$

$$Δ {\dot{U}}_{m} - Δ {\dot{U}}_{n} = ( Δ {\dot{I}}_{m} - {Y}_{m} Δ {\dot{U}}_{m} ) {Z}_{mn} \qquad ( 3 )$$

wherein \dot{U}ₘ represents the voltage phasor associated with time at node m, Δ\dot{U}ₘ represents the change of the voltage phasor associated with the predetermined time period at node m, \dot{U}ₙ represents the voltage phasor synchronized with \dot{U}ₘ at node n, Δ\dot{U}ₙ represents the change of the voltage phasor synchronized with Δ\dot{U}ₘ at node m, İₘ represents the current phasor associated with time at node m, İₙ represents the change of the current phasor synchronized with İₘ at node n, Δİₙ represents the change of the current phasor synchronized with Δİₘ at node n.

The change of voltage phasor and the change of current phasor described above are described with the following equations:

$$Δ {\dot{U}}_{m} = {\dot{U}}_{m} ( t + Δ T ) - {\dot{U}}_{m} ( t ) \qquad ( 4 )$$

$$Δ {\dot{U}}_{n} = {\dot{U}}_{n} ( t + Δ T ) - {\dot{U}}_{n} ( t ) \qquad ( 5 )$$

$$Δ {\dot{I}}_{m} = {\dot{I}}_{m} ( t + Δ T ) - {\dot{I}}_{m} ( t ) \qquad ( 6 )$$

$$Δ {\dot{I}}_{n} = {\dot{I}}_{n} ( t + Δ T ) - {\dot{I}}_{n} ( t ) \qquad ( 7 )$$

Taking equations (4) and (5) as an example, \dot{U}ₘ (t) represents the voltage phasor at time point t at node m, \dot{U}ₘ (t+ΔT) represents the voltage phasor at time point t+ΔT at node m, where ΔT represents a predetermined time period between time point t and time point t+ΔT, e.g. 0.5 seconds. \dot{U}ₙ (t) represents the voltage phasor at time point t at node n, i.e. the voltage phasor at node n synchronized with \dot{U}ₘ (t), \dot{U}ₙ (t+ΔT) represents the voltage phasor at time point t+ΔT at node n, i.e. the voltage phasor at node n synchronized with \dot{U}ₘ (t+ΔT).

The equations (2), (3) are processed such that the equivalent impedance Zₘₙ is expressed based on the voltage phasor, the change of the voltage phasor, the current phasor, and the change of the current phasor:

$${Z}_{mn} = \frac{Δ {\dot{U}}_{m} {\dot{U}}_{n} - Δ {\dot{U}}_{n} {\dot{U}}_{m}}{Δ {\dot{I}}_{m} {\dot{U}}_{m} - Δ {\dot{U}}_{m} {\dot{I}}_{m}} \qquad ( 8 )$$

From equation (8), the equivalent impedance between node m and node n need only be calculated by obtaining the voltage phasor and the change of the voltage phasor at node n in addition to the electrical information of itself at node m.

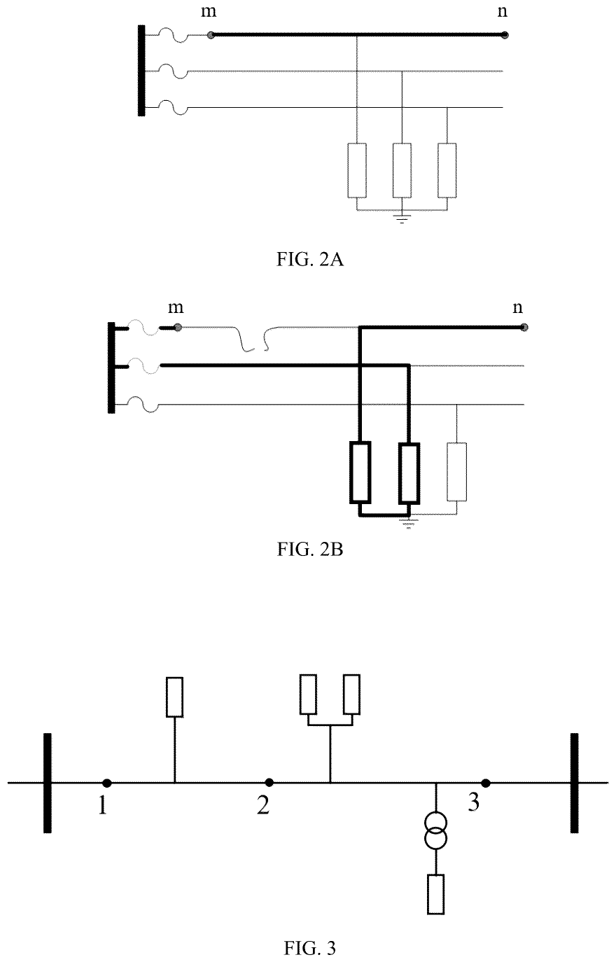

FIG. 2A and FIG. 2B exemplarily illustrate schematic diagrams of normal operation and broken conductor faults, respectively, in a three-phase connection diagram.

FIG. 2A exemplarily illustrates a schematic diagram of the normal operation of the power system in a three-phase connection diagram.

As shown in FIG. 2A, the power system includes a three-phase power supply and a three-phase electrical load connected to the three-phase power supply. Between the nodes m, n on one of the phase power supply lines, the electrical connection indicated by the thick line in the figure is from the node m to the node n or from the node n to the node m without passing through the phase circuit of the electric load.

FIG. 2B exemplarily illustrates a schematic diagram of a broken conductor fault of the power system of FIG. 2A.

A broken conductor fault occurs, for example, on one of the phase power supply lines, the point of fault being located between the nodes m, n. The direct connection of node m and node n is broken due to the broken conductor fault. However, due to the presence of the phase circuits of the three-phase consumer load, there is still an electrical connection between the node m and the node n (indicated by the bold line in the illustration), i.e. the node m and the node n form an electrical circuit through two phase power supply lines and two phase circuits of the consumer load.

In the case of normal operation, the electrical connection between nodes m, n in FIG. 2A passes only through the grid lines, and the linked impedance between nodes m, n is not greater than the line impedance between nodes m, n. In the case of a broken conductor fault, the electrical connection between nodes m, n in FIG. 2B passes through the phase circuits of the electrical load with a significantly increased impedance, and the linked impedance between nodes m, n is significantly greater than the line impedance between nodes m, n. Based on this recognition, the idea underlying the present disclosure is to detect whether there is a broken conductor fault between the nodes m, n by determining the linked impedance between the nodes m, n and comparing with a threshold value, the threshold value being associated with the line impedance.

The electrical loads shown in the drawings are merely exemplary, and may be replaced with distributed power supplies or the like.

The single-phase broken conductor shown in FIG. 2A and FIG. 2B is exemplary only, and embodiments according to the present disclosure can also be applied in the case of a two-phase broken conductor fault.

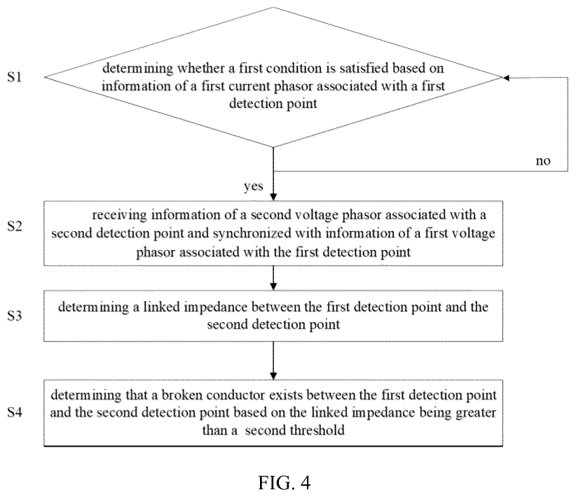

A method for broken conductor detection of a power system according to embodiments of the present disclosure is described in more detail next with the aid of FIG. 3 and FIG. 4.

FIG. 3 illustrates a schematic diagram of detection points according to an embodiment of the present disclosure.

According to an embodiment of the present disclosure, a plurality of detection points are provided on power grid lines so that fault detection is performed in sections from detection point to detection point. The detection points can be arranged not only on the main electrical line of the grid but also on the branch lines. In this way, not only can the broken conductor detection be made comprehensively, but the broken conductor protection can be triggered in sections after the detection of a broken conductor fault, without affecting the normal operation of other parts of the power system.

According to an embodiment of the present disclosure, the detection points can be implemented, for example, as a demarcation switch, a circuit breaker, or the like.

In FIG. 3, three detection points are exemplarily provided on the electrical main line, namely a first detection point 1, a second detection point 2 and a third detection point 3. Between the detection points there are connected electrical loads or distributed power supplies, respectively.

FIG. 4, with reference to FIG. 3, illustrates a schematic flow diagram of a method for broken conductor detection of a power system according to an embodiment of the present disclosure, the method including steps S1-S4.

Preferably, the method according to an embodiment of the present disclosure is performed at each detection point, taking the performance of the method at the first detection point 1 as an example for explanation.

In a first step S1, it can be determined whether a first condition is fulfilled, for example based on information of a first current phasor associated with a first detection point 1 in the power system. Preferably, the first condition is that the magnitude of a changing phasor of the first current phasor in a predetermined time period between the first and second time points is greater than a predetermined first threshold. In the present disclosure, the second time point occurs, for example, after the first time point. The first condition is represented by the following equation:

$$\vert Δ {\dot{I}}_{1} \vert > {TH}_{1} \qquad ( 9 )$$

wherein Δİ₁ represents the changing phasor of the first current phasor 11 over a predetermined period of time between the first time point and the second time point. |·| represents the magnitude of the phasor. The length of the predetermined period of time can be set as desired, for example between 0.02 seconds and 1 second, such as 0.5 seconds or the like. TH₁ represents a predetermined first threshold.

The first step S1 of determining whether the first condition is fulfilled means that the current phasor at the first detection point 1 is monitored and the broken conductor detection is turned on when its magnitude occurs to exceed a predetermined threshold. This is due to the fact that the current phasor changes when a broken conductor fault occurs. In this way, broken conductor detection can be performed with higher accuracy, higher responsivity and at the same time lower communication costs.

Based on determining that the information of the first current phase phasor associated with the first detection point 1 satisfies the first condition, i.e. in case of “yes”, a second step S2 is performed. Based on determining that the information of the first current phasor associated with the first detection point 1 does not satisfy the first condition, i.e. in case of “no”, a return to the first step S1 is performed, enabling continuous monitoring of the information of the first current phasor over time.

In a second step S2, information of a second voltage phasor associated with a second detection point 2 can be received, for example based on determining that the first condition is fulfilled. The second detection point 2 is a detection point adjacent to the first detection point 1 in the power system. The information of the second voltage phasor is synchronized with the information of the first voltage phasor associated with the first detection point 1.

According to an embodiment of the present disclosure, the information of the first current phasor can include, for example, a phasor of the first current phasor at a first time point and a phasor of the first current phasor at the second time point, and the information of the first voltage phasor can include, for example, a phasor of the first voltage phasor at the first time point and a phasor of the first voltage phasor at the second time point. Using the information of the first current phasor and the information of the first voltage phasor, not only the first current phasor at the first and second time points can be derived, but also a changing phasor of the first current phasor during a predetermined time period between the first and second time points can be derived; Not only the first voltage phasor at the first and second time points can be derived, but also a changing phasor of the first voltage phasor over a predetermined time period between the first and second time points can be derived.

Advantageously, only the information of the second voltage phasor associated with the second detection point 2 needs to be received in the second step S2, and not the information of the second current phasor associated with the second detection point 2, reducing the amount of information that needs to be transmitted.

In a third step S3, the linked impedance between the first detection point 1 and the second detection point 2 can be determined, e.g. based on information of the first current phasor, information of the first voltage phasor and information of the second voltage phasor.

According to an embodiment of the present disclosure, the information of the second voltage phasor can include, for example, a phasor of the second voltage phasor at a first time point and a phasor of the second voltage phasor at a second time point, optionally, the information of the second voltage phasor includes, for example, a phasor at the second time point and a changing phasor of the second voltage phasor over a predetermined time period. Determining the linked impedance comprises calculating the actual value of the linked impedance, the calculation being based on equation (8), which in the present embodiment can for example be rewritten as:

$${Z}_{12} = \vert \frac{Δ {\dot{U}}_{1} {\dot{U}}_{2} - Δ {\dot{U}}_{2} {\dot{U}}_{1}}{Δ {\dot{I}}_{1} {\dot{U}}_{1} - Δ {\dot{U}}_{1} {\dot{I}}_{1}} \vert \qquad ( 10 )$$

wherein Z₁₂ represents the linked impedance between the first detection point 1 and the second detection point 2, \dot{U}₁ represents the phasor of the first voltage phasor at the second time point, 401 represents the difference between the phasor of the first voltage phasor at the second time point and the phasor of the first voltage phasor at the first time point and is calculated e.g. by means of equation (4), \dot{U}₂ represents the phasor of the second voltage phasor at the second time point, Δ\dot{U}₂ represents the difference between the phasor of the second voltage phasor at the second time point and the phasor of the second voltage phasor at the first time point and is calculated e.g. by means of equation (5), İ₁ represents the phasor of the first current phasor at the second time point, Δİ₁ represents the difference between the phasor of the first current phasor at the second time point and the phasor of the first current phasor at the first time point and is calculated e.g. by means of equation (6).

With this embodiment, the actual value of the linked impedance between the first detection point 1 and the second detection point 2 can be accurately calculated.

According to a further embodiment of the present disclosure, the information of the second voltage phasor can for example comprise only the magnitude of the phasor of the second voltage phasor at the second time point and the magnitude of the changing phasor of the second voltage phasor within a predetermined time period between the first time point and the second time point. İₙ this case, determining the linked impedance comprises calculating an approximation of the linked impedance by approximating equation (10):

$${Z}_{12} \approx \frac{\vert Δ {\dot{U}}_{1} \vert \vert {\dot{U}}_{2} \vert - \vert Δ {\dot{U}}_{2} \vert \vert {\dot{U}}_{1} \vert}{\vert Δ {\dot{I}}_{1} {\dot{U}}_{1} - Δ {\dot{U}}_{1} {\dot{I}}_{1} \vert} \qquad ( 11 )$$

From equation (11), calculating the approximation of the linked impedance does not require receiving the complete phasor (i.e. not only the magnitude but also the phase angle) of the second voltage phasor at the first and second time points, but only the magnitude of the phasor of the second voltage phasor at the second time point and the magnitude of the changing phasor of the second voltage phasor within the predetermined time period between the first and second time points.

With this embodiment, on the one hand, since the calculation of the approximation requires only the magnitude information and not the phase angle information, the requirements for synchronization accuracy of the data in the calculation can be reduced, and on the other hand, since less information needs to be transmitted, the amount of data transmitted in the communication can be reduced. Compared to calculating the actual value of the linked impedance, the synchronization accuracy can be relaxed, for example, to between 1 millisecond and 5 milliseconds in order to calculate the approximate value.

In a fourth step S4, it can be determined that there is a broken conductor between the first detection point 1 and the second detection point 2, for example based on the linked impedance being greater than a predetermined second threshold.

According to the concept underlying the present disclosure described with reference to FIG. 2A and FIG. 2B, the linked impedance between the detection points is not greater than the line impedance between the detection points in the absence of a broken conductor between the detection points, and the linked impedance between the detection points is significantly greater than the line impedance between the detection points in the presence of a broken conductor between the detection points. A broken conductor detection can thus be performed based on a comparison of the linked impedance with a predetermined second threshold value.

According to an embodiment of the present disclosure, the second threshold can for example be determined based on the line impedance between the first detection point 1 and the second detection point 2. Preferably, in order to avoid errors caused by small fluctuations of the line, the second threshold value is a multiple, e.g. a factor of 2, of the line impedance between the first detection point 1 and the second detection point 2. For example, empirically, every 10 km of line may have an impedance of 2 ohms, and therefore, when the length of the line between the first detection point 1 and the second detection point 2 is 5 km, the line impedance may be 1 ohm, and the second threshold can be determined to be 2 ohms; when the length of the line between the first detection point 1 and the second detection point 2 is 20 km, the line impedance may be 4 ohms, and the second threshold value can be determined to be 8 ohms. This second threshold may be set according to the actual situation of the line impedance between the first detection point 1 and the second detection point 2 and the requirement for accuracy.

The method according to embodiments of the present disclosure is preferably performed at each detection point, so that each detection point can detect whether there is a broken conductor between itself and an adjacent detection point in time. According to an embodiment of the present disclosure, this broken conductor detection and subsequent disconnection of the detection point can be done, for example, within 1 second, enabling rapid power-down of the broken conductor before it touches the ground or trees, avoiding risks reliably and efficiently.

The method according to the embodiments of the present disclosure, which calculates the linked impedance between the detection points based on the current phasor and the voltage phasor of the detection points, is simple to set, easy to implement, and is applicable with the existing infrastructure of the power system, such as the synchronization device and the communication device. The method reduces communication costs by communicating data only after a certain degree of fluctuation in the current phase phasor is detected. Furthermore, based on the method, it is possible to disconnect, for example, the first detection point 1 in case it is determined that there is a broken conductor between the first detection point 1 and the second detection point 2, thereby enabling a selective de-energization of the line between the detection points without affecting the normal operation of the other parts of the power system.

Further, the method according to embodiments of the present disclosure is highly reliable in the event of a broken conductor fault, reduces the requirement for accuracy of data synchronization by requiring only the reception of voltage phasors, preferably the magnitude of the voltage phasors, of adjacent detection points, makes it possible to synchronize using less costly means of synchronization, e.g. by means of GPS, and reduces the cost of communication, e.g. the required data transmission can be achieved using 4G communication, which is particularly advantageous in areas where high cost means of communication, e.g. fiber optic communication, are not provided.

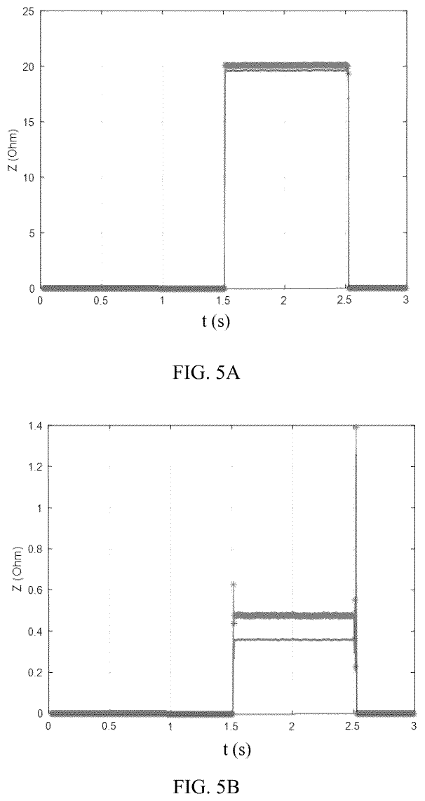

FIG. 5A and FIG. 5B illustrate schematic diagrams of simulation results of a method according to an embodiment of the present disclosure.

The simulation is for example based on the occurrence of a broken conductor between the first detection point 1 and the second detection point 2 in the power system shown in FIG. 3. In the simulation illustration, the horizontal axis represents time t in seconds(s), the vertical axis represents the magnitude of impedance Z in ohms (Ohm), the thinner black line represents the actual value of the calculated linked impedance, and the thicker gray line represents the approximate value of the calculated linked impedance.

In this embodiment, the predetermined second threshold is, for example, 5 ohms. The predetermined time period between the first time point and the second time point is, for example, 1 second.

FIG. 5A illustrates the linked impedance between the first detection point 1 and the second detection point 2 calculated at the first detection point 1 or the second detection point 2 according to the method according to an embodiment of the present disclosure.

As shown in FIG. 5A, during 0 seconds to 1.5 seconds, the linked impedance is 0, since the current phasor at the detection point does not satisfy the first condition and thus does not trigger the calculation of the linked impedance. At 1.5 seconds, a broken conductor occurs between the first detection point 1 and the second detection point 2, the current phasors at the first detection point 1 and the second detection point 2 both satisfy the first condition, trigger the calculation of the linked impedance, both the actual value and the approximate value of the linked impedance are significantly larger than the second threshold, determining that there is a broken conductor fault between the first detection point 1 and the second detection point 2. After 2.5 seconds the linked impedance reverts to 0, meaning that the current phasor at the detection point no longer satisfies the first condition.

FIG. 5B illustrates the linked impedance between the second detection point 2 and the third detection point 3 calculated at the third detection point 3 according to the method according to an embodiment of the present disclosure.

As shown in FIG. 5B, during 0 seconds to 1.5 seconds, the linked impedance is 0, since the current phasor at the third detection point 3 does not satisfy the first condition and thus does not trigger the calculation of the linked impedance. At 1.5 seconds, a broken conductor occurs between the first detection point 1 and the second detection point 2, the current phasor at the third detection point 3 likewise fluctuates such that the first condition may be satisfied, triggering the calculation of the linked impedance, but, both the actual value and the approximate value of the linked impedance are significantly smaller than the second threshold, determining that there is no broken conductor fault between the second detection point 2 and the third detection point 3. In the subsequent process, the third detection point 3 will not be de-energized.

As can be seen from the simulation results shown in FIG. 5A and FIG. 5B, the method according to an embodiment of the present disclosure is capable of accurately and quickly detecting at a detection point whether there is a broken conductor fault between the detection point and an adjacent detection point. In addition, the approximate value of the linked impedance is close to the actual value of the linked impedance to a higher degree, and can also be used for broken conductor detection with a high degree of accuracy.

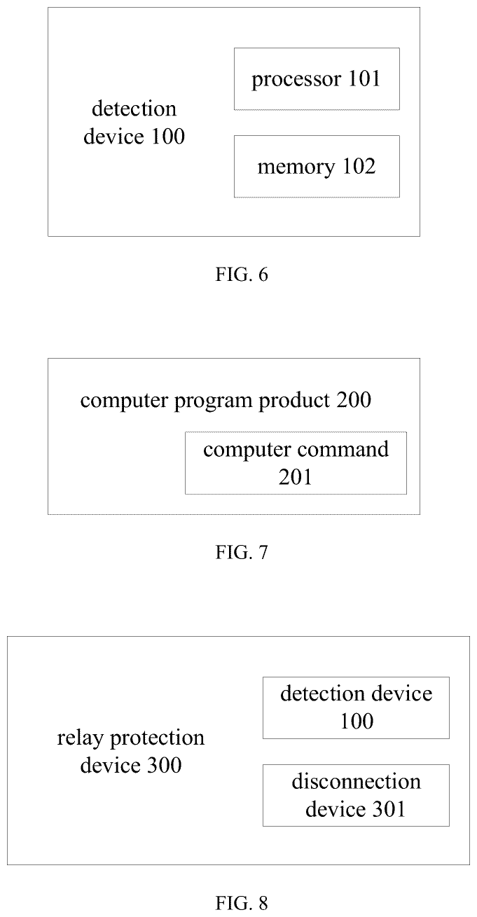

FIG. 6 illustrates a schematic diagram of a detection device according to an embodiment of the present disclosure.

As shown in FIG. 6, the detection device 100 can include one or more processors 101, and one or more memories 102. The memory 102 has stored therein computer commands that, when executed by the processor 101, can perform the method according to one of the embodiments of the present disclosure.

Preferably, a detection device 100 is provided at each detection point of the power system.

The processor in the embodiments of the present disclosure can be an integrated circuit chip, having processing capability of signals. The processor can be a general-purpose processor, a digital signal processor (DSP), an application specific integrated circuit (ASIC), an off-the-shelf programmable gate array (FPGA) or other programmable logic device, discrete gate or transistor logic, discrete hardware components. The methods, steps, and logical block diagrams disclosed in the embodiments of the present application can be implemented or performed. The general-purpose processor can be a microprocessor or the processor can be any conventional processor or the like and can be of an X86 architecture or an ARM architecture.

According to the detection device of the embodiment of the present disclosure, the linked impedance between the detection points is calculated based on the current phasor and the voltage phasor of the detection points, the structure is simple, and the cost is low. The detection device reduces communication costs by communicating data only after a certain degree of fluctuation in the current phase phasor is detected. Furthermore, based on the detection device, it is possible to disconnect, for example, the first detection point 1 in case it is determined that there is a broken conductor between the first detection point 1 and the second detection point 2, thereby enabling a selective de-energization of the line between the detection points without affecting the normal operation of the other parts of the power system.

Further, the detection device according to embodiments of the present disclosure is highly reliable in the event of a broken conductor fault, reduces the requirement for accuracy of data synchronization by requiring only the reception of voltage phasors, preferably the magnitude of the voltage phasors, of adjacent detection points, makes it possible to synchronize using less costly means of synchronization, for example by means of GPS, and reduces the cost of communication, for example the required data transmission can be achieved using 4G communication, which is particularly advantageous in areas where high cost means of communication, for example optical fiber communication, are not provided.

FIG. 7 illustrates a schematic diagram of a computer program product according to an embodiment of the present disclosure.

As illustrated in FIG. 7, the computer program product 200 can include computer commands 201, which, when executed by a processor, can be used to implement a method according to one of the embodiments of the present disclosure.

According to the computer program product according to an embodiment of the present disclosure, the linked impedance between the detection points is calculated based on the current phasor and the voltage phasor of the detection points, the setup is simple, and the implementation is easy. The computer program product reduces communication costs by communicating data only after a certain degree of fluctuation in the current phase phasor is detected. Furthermore, based on the computer program product, selective de-energization of lines between detection points can be achieved without affecting the proper functioning of other parts of the power system.

Further, the computer program product according to embodiments of the present disclosure is highly reliable in the event of a broken conductor fault, reduces the requirement for accuracy of data synchronization by requiring only the reception of voltage phasors, preferably the magnitude of the voltage phasors, of adjacent detection points, makes it possible to synchronize using less costly means of synchronization, e.g. by means of GPS, and reduces the cost of communication, e.g. the required data transmission can be achieved using 4G communication, which is particularly advantageous in areas where high cost means of communication, e.g. fiber optic communication, are not provided.

FIG. 8 illustrates a schematic diagram of a relay protection device according to an embodiment of the present disclosure.

As shown in FIG. 8, the relay protection device 300 can include the detection device 100 according to an embodiment of the present disclosure and a disconnection device 301. The disconnection device 301 can disconnect the first detection point from the power system, for example, based on the detection device 100 determining that there is a broken conductor between the first detection point and the second detection point.

That is, the relay protection device 300 at a first detection point is preferably only responsible for the de-energization of the first detection point and not for the de-energization of an adjacent second detection point upon detection of the presence of a broken conductor between the first detection point and the second detection point, and likewise, the relay protection device 300 at a second detection point is also preferably only responsible for the de-energization of the second detection point upon detection of the presence of a broken conductor between the first detection point and the second detection point. According to an embodiment of the present disclosure, in a line in which a broken conductor fault occurs, detection points at both ends can determine that there is a broken conductor, and broken conductor protection is achieved by deenergizing themselves so that the line in which the broken conductor fault occurs is disconnected at both ends. In this manner, the relay protection device 300 can perform a disconnection action without waiting for an adjacent detection point to communicate back whether or not it is also determined that there is a broken conductor, reducing the response time of the broken conductor protection.

According to the relay protection device of the embodiment of the present disclosure, the linked impedance between the detection points is calculated based on the current phasor and the voltage phasor of the detection points, the setup is simple, and the implementation is easy. The relay protection device reduces communication costs by communicating data only after a certain degree of fluctuation in the current phase phasor is detected. In addition, the relay protection device enables selective de-energization of lines between detection points without affecting the proper operation of other parts of the power system. Additionally, the relay protection device is only responsible for the power outage of the local detection point, improving the response speed of the broken conductor protection.

Further, the relay protection device according to an embodiment of the present disclosure is highly reliable in the event of a broken conductor fault, reduces the requirement for accuracy of data synchronization by requiring only the reception of voltage phasors, preferably the magnitude of the voltage phasors, of adjacent detection points, makes it possible to use less costly means of synchronization, for example by means of GPS, and makes it possible to reduce the cost of communication, for example the required data transmission can be achieved using 4G communication, which is particularly advantageous in areas where high cost means of communication, for example optical fiber communication, are not provided.

It is noted that the flowchart and block diagrams in the drawings illustrate the architecture, functionality, and operation of possible implementations of systems, methods, and computer program products according to various embodiments of the present disclosure. In this regard, each block in the flowchart or block diagrams can represent a module, segment, or portion of code, which includes at least one executable command for implementing the specified logical function(s). It should also be noted that, in some alternative implementations, the functions noted in the block can occur out of the order noted in the drawings. For example, two blocks shown in succession may, in fact, be executed substantially concurrently, or the blocks can sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or operations or combinations of special purpose hardware and computer commands.

In general, the various example embodiments of the disclosure can be implemented in hardware or special purpose circuits, software, firmware, logic or any combination thereof. Certain aspects can be implemented in hardware, while other aspects can be implemented in firmware or software which may be executed by a controller, microprocessor or other computing device. While aspects of embodiments of the present disclosure are illustrated or described as block diagrams, flow charts, or using some other pictorial representation, it is understood that the blocks, apparatus, systems, techniques or methods described herein can be implemented in, as non-limiting examples, hardware, software, firmware, special purpose circuits or logic, general purpose hardware or controller or other computing devices, or some combination thereof.

The example embodiments of the present disclosure described in detail above are merely illustrative, and are not limiting. It will be understood by those skilled in the art that various modifications and combinations of these embodiments or features thereof can be made without departing from the principles of the present disclosure, such modifications shall fall within the scope of the present disclosure.

What is claimed is:

1. A method for broken conductor detection of a power system, comprising:
determining whether a first condition is satisfied based on information of a first current phasor associated with a first detection point in the power system, wherein the first condition is that a magnitude of a change of the first current phasor over a predetermined time period between a first time point and a second time point is greater than a predetermined first threshold;
based on determining that the first condition is satisfied, receiving information of a second voltage phasor associated with a second detection point and synchronized with information of a first voltage phasor associated with the first detection point, wherein the second detection point is a detection point in the power system that is adjacent to the first detection point;
determining a linked impedance between the first detection point and the second detection point based on the information of the first current phasor, the information of the first voltage phasor and the information of the second voltage phasor; and
determining that a broken conductor exists between the first detection point and the second detection point based on the linked impedance being greater than a predetermined second threshold.

2. The method of claim 1, wherein
the information of the first current phasor comprises a phasor of the first current phasor at the first time point and a phasor of the first current phasor at the second time point, the information of the first voltage phasor comprises a phasor of the first voltage phasor at the first time point and a phasor of the first voltage phasor at the second time point.

3. The method of claim 2, wherein
the information of the second voltage phasor comprises a magnitude of a phasor of the second voltage phasor at the second time point and a magnitude of a changing phasor of the second voltage phasor over the predetermined period of time, and wherein determining the linked impedance comprises calculating an approximation of the linked impedance.

4. The method of claim 3, wherein the approximation of the linked impedance is calculated based on the following equation:
$${Z}_{12} \approx \frac{\vert Δ {\dot{U}}_{1} \vert \vert {\dot{U}}_{2} \vert - \vert Δ {\dot{U}}_{2} \vert \vert {\dot{U}}_{1} \vert}{\vert Δ {\dot{I}}_{1} {\dot{U}}_{1} - Δ {\dot{U}}_{1} {\dot{I}}_{1} \vert}$$
wherein Z₁₂ represents the linked impedance, \dot{U}₁ represents the phasor of the first voltage phasor at the second time point, Δ\dot{U}₁ represents the difference between the phasor of the first voltage phasor at the second time point and the phasor of the first voltage phasor at the first time point, \dot{U}₂ represents the phasor of the second voltage phasor at the second time point, Δ\dot{U}₂ represents the difference between the phasor of the second voltage phasor at the second time point and the phasor of the second voltage phasor at the first time point, İ₁ represents the phasor of the first current phasor at the second time point, 411 represents the difference between the phasor of the first current phasor at the second time point and the phasor of the first current phasor at the first time point, and |·| represents the magnitude of the phasor.

5. The method of claim 2, wherein
the information of the second voltage phasor comprises a phasor of the second voltage phasor at the first time point and a phasor of the second voltage phasor at the second time point, and wherein determining the linked impedance comprises calculating an actual value of the linked impedance.

6. The method of claim 5, wherein the actual value of the linked impedance is calculated based on the following equation:
$${Z}_{12} = \vert \frac{Δ {\dot{U}}_{1} {\dot{U}}_{2} - Δ {\dot{U}}_{2} {\dot{U}}_{1}}{Δ {\dot{I}}_{1} {\dot{U}}_{1} - Δ {\dot{U}}_{1} {\dot{I}}_{1}} \vert$$
wherein Z₁₂ represents the linked impedance, \dot{U}₁ represents the phasor of the first voltage phasor at the second time, Δ\dot{U}₁ represents the difference between the phasor of the first voltage phasor at the second time and the phasor of the first voltage phasor at the first time, \dot{U}₂ represents the phasor of the second voltage phasor at the second time, Δ\dot{U}₂ represents the difference between the phasor of the second voltage phasor at the second time and the phasor of the second voltage phasor at the first time, İ₁ represents the phasor of the first current phasor at the second time, Δİ₁ represents the difference between the phasor of the first current phasor at the second time and the phasor of the first current phasor at the first time, and |·| represents the magnitude of the phasor.

7. The method of claim 1, wherein
determining the second threshold based on the line impedance between the first detection point and the second detection point.

8. A detection device for broken conductor detection of a power system, comprising:
at least one processor; and
at least one memory in which is stored an executable program which, when the executable program executed by the at least one processor, performs a method of claim 1.

9. A relay protection device comprising a detection device of claim 8 and a disconnection device that disconnects the first detection point from the power system based on the detection device determining that there is a broken conductor between the first detection point and the second detection point.
